(19) United States
(12) Patent Application Publication
(10) Pub. No.: US 2008/0068088 A1
(43) Pub. Date: Mar. 20, 2008

(54) AMPLIFIER CIRCUIT

(76) Inventor: Christoph Bromberger, Heilbronn (DE)

Correspondence Address: MG-IP Law, PLLC, P.O. BOX 1364, FAIRFAX, VA, 22038-1364, US

(21) Appl. No.: 11/860,531

(22) Filed: Sep. 24, 2007

Related U.S. Application Data
(63) Continuation of application No. PCT/EP2006/002445, filed on Mar. 17, 2006.

(30) Foreign Application Priority Data
Mar. 23, 2006 (DE) DE102005013385

(51) Int. Cl. H03F 3/04

(52) U.S. Cl. 330/288; 330/250

(57) ABSTRACT

An amplifier circuit is provided for amplifying an input signal with a vertically integrated cascode. The cascode comprises a collector semiconductor region of a collector, a first base semiconductor region, adjacent to the collector semiconductor region, of a first base, a second base semiconductor region of a second base, an intermediate base semiconductor region adjacent to both the first base semiconductor region and the second base semiconductor region, and an emitter semiconductor region, adjacent to the second base semiconductor region, of an emitter. A signal input is connected to the second base and the first base is connected via a network to the second base in such a way that a small signal voltage at the first base is coupled to a small signal voltage at the second base and/or a small signal current through the second base.

This nonprovisional application is a continuation of International Application No. PCT/EP2006/002445, which was filed on Mar. 17, 2006, and which claims priority to German Patent Application No. DE 102005013385, which was filed in Germany on Mar. 23, 2006, and which are both herein incorporated by reference.

### BACKGROUND OF THE INVENTION

1. Field of the Invention

The present invention relates to an amplifier circuit.

2. Description of the Background Art

Cascode stages are known, particularly those with two bipolar transistors, for example, two npn transistors or two pnp transistors, the collector of the first of the two transistors being connected to the emitter of the second of the two transistors.

Cascode stages are driven predominantly in the standard configuration described below, as is shown in FIG. 2. The emitter of the second transistor Q2′ is connected to ground (emitter circuit) whereas an input signal is applied at the base. The base of the first transistor Q1′ has a fixed direct voltage U_{B} (base circuit), whereas the collector is connected via a load resistor R_{L}′ to the supply voltage V_{cc}. Cascode circuits with a standard configuration are often used as a replacement for single transistors. A reason for this is the excellent constancy of the output current with the output voltage at a fixed control current.

Another known circuit topology for the replacement of a single transistor by a cascode circuit is the feedback circuit of FIG. 3. In this case, the feedback branch comprising resistors R1″ and R2″ is connected to both the load resistor R_{L}″ and to the base of the first transistor Q1″, so that the output voltage is fed back to the input of the first transistor Q1″ and to the input of the second transistor Q2″.

### SUMMARY OF THE INVENTION

It is therefore an object of the present invention to provide an amplifier circuit, which reduces as much as possible the intermodulation distortions during use of a vertically integrated cascode structure.

Accordingly, an amplifier circuit is provided for amplifying an input signal, particularly a high-frequency signal of a radio transmission. This amplifier circuit has a vertically integrated cascode, which in turn has a collector semiconductor region of a collector, a first base semiconductor region, adjacent to the collector semiconductor region, of a first base, a second base semiconductor region of a second base, an intermediate base semiconductor region adjacent to both the first base semiconductor region and the second base semiconductor region, and an emitter semiconductor region, adjacent to the second base semiconductor region, of an emitter.

This type of vertically integrated cascode can be integrated with other components on a semiconductor wafer. Preferably, the vertically integrated cascode has p-n junctions oriented substantially planar to the wafer surface and/or substantially parallel to one another. The signal input according to the invention is connected to the second base.

In an aspect, the first base is connected via a network, for example, comprising resistors, to the second base in such a way that a small signal voltage at the first base is coupled to a small signal voltage at the second base. For this purpose, in combination or alternatively, the network is designed such that a small signal current through the first base is coupled to a small signal current through the second base. The coupling has the effect that the signal at the first base depends on changes in the signal at the second base.

The network can include pure passive elements or can contain in addition active components or circuits, such as, for example, a current mirror. An electrical coupling is thereby preferably understood to be any coupling that produces a dependence of the signal at the first base on the signal at the second base. For example, capacitive, inductive, or magnetic couplings are possible. Especially preferred, however, is a simple voltage coupling through the use of a voltage divider, which is formed particularly by resistors. The mathematical relationship between a potential at the first base and a potential at the second base can thereby be, for example, logarithmic, exponential, or proportional.

Am embodiment of the invention provides that the first base can be connected via the network to the second base in such a way that the small signal voltage at the first base is substantially (directly) proportional to the small signal voltage at the second base and/or the small signal current through the first base is substantially (directly) proportional to the small signal current through the second base. This type of (direct) proportionality can be achieved, for example, by mutually connected resistors, which together with parasitic capacitors produce an impedance with a negligible frequency dependence. Another possible embodiment can be achieved by a capacitive coupling of the first base terminal to the second base terminal.

To develop the invention further, it is provided that the network is designed in such a way that the small signal voltage at the first base is substantially in phase to the small signal voltage at the second base and/or the small signal current through the first base is substantially in phase to the small signal current through the second base. Substantially in phase is taken to mean that the phase input is less than 20°, preferably less than 10°, and is zero in the ideal case.

The first base may not be connected to the collector, so that preferably the small signal voltage at the first base and/or the small signal current through the first base are substantially independent of the collector-emitter voltage.

Another embodiment of the invention provides that in addition to the signal coupling the network can be designed for setting the operating point of the first base and/or the second base. The network sets an operating point base potential, for example, by a suitable voltage divider comprising resistors.

The network can have a voltage divider, which is connected to the first base and the second base. Preferably, this voltage divider is formed by series-connected resistors or series-connected capacitors.

An embodiment of the invention provides that the network can be designed in such a way that a first base voltage of the first base is fed to a second base voltage of the second base at a substantially constant interval. The voltage at the first base is therefore advantageously formed from the sum of the small signal at the second base and an offset voltage.

An alternative development of the invention provides that the first base and the second base can be connected to one another via a current mirror.

In embodying the invention, at least one of the base semiconductor regions can have a silicon-germanium mixed crystal.

Another aspect of the invention is the use of a previously explained amplifier circuit in a high-frequency circuit used in communication technology, particularly in mobile radio technology or automotive technology.

An embodiment of the invention provides that the first base and/or second base cam be connected to a current source or current drain, which preferably has a high impedance for the input signal. The current source or the current drain in a preferred embodiment of the invention is a DC source, advantageously a temperature-insensitive reference current source, which preferably has a higher impedance relative to the resistors and/or other impedances of the amplifier circuit.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1a is an amplifier circuit with a vertically integrated cascode,

FIG. 1b is a network formed by two resistors,

FIG. 1c is a network formed by two resistors, a capacitor, and an inductor,

FIG. 2 is a standard configuration of a cascode according to the state of the art,

FIG. 3 is a configuration of a cascode with a feedback branch according to the state of the art,

FIG. 4 is a circuit detail of the vertically integrated cascode,

FIG. 5 is a schematic diagram of a vertically integrated cascode,

FIG. 6 is another amplifier circuit with a vertically integrated cascode, and

FIGS. 7a and 7b are simple embodiments of a current source or a current drain with high output impedance.

### DETAILED DESCRIPTION

The vertically integrated cascode, also called a tetrode, represents a special, high-frequency-capable integrated component. This type of vertically integrated cascode is configured, for example, with a resistive load between the collector of the vertically integrated cascode and a supply voltage. The first base is typically applied to a fixed bias voltage, the input signal to the second base, and the emitter to ground. With a declining collector voltage, therefore a rising load current, the current in the second base of the vertically integrated cascode increases, and herewith the voltage between the second base and the emitter.

The transient behavior of a high-frequency component depends in particular on the operating point. Certain embodiments of the vertically integrated cascode show an optimal transient behavior at voltages between the emitter and the second base that are above the voltage at which the amplification peaks. If the selected operating point for feeding current to the resistive load is within a range with an approximately optimal transient behavior of the vertically integrated cascode, it follows that the amplification can decline with a declining collector voltage. This can result in a current-dependent amplification during the power supply to a resistive load, which can cause a poorer intermodulation behavior.

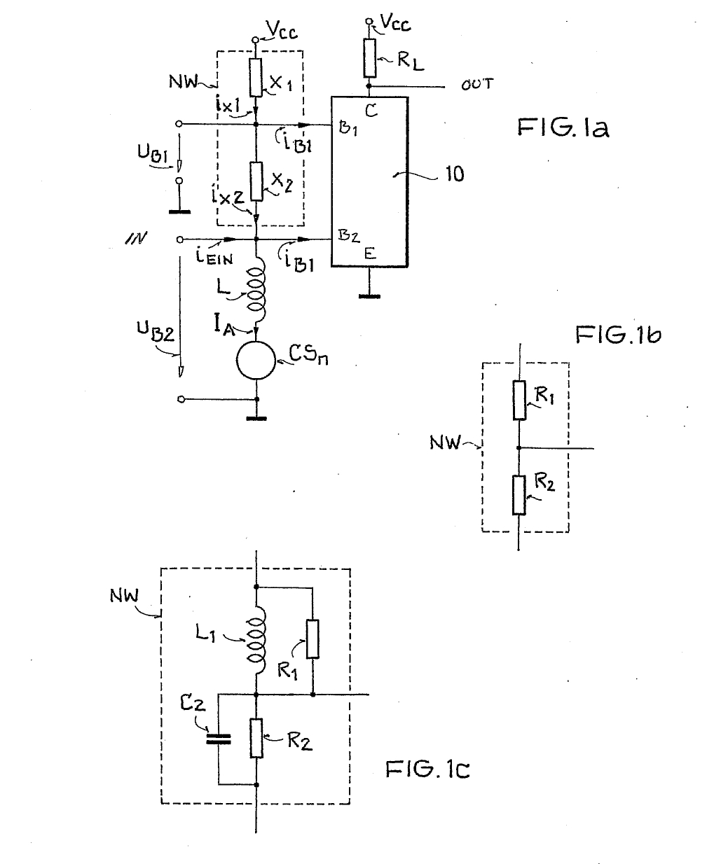

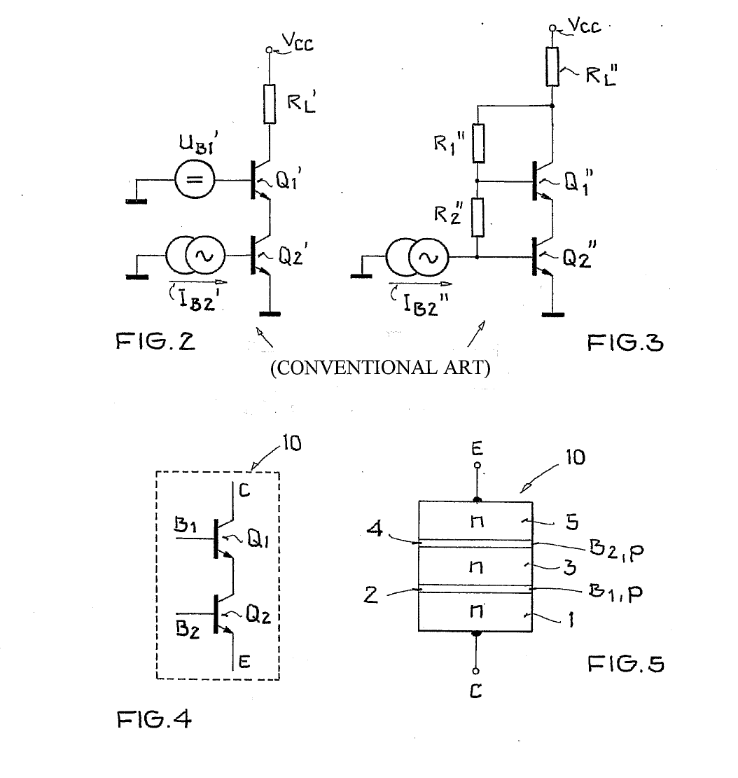

The circuit of FIG. 1a now brings about that around the operating points with approximately optimal transient behavior of a vertically integrated cascode 10, it is possible to achieve an improved constancy of amplification along a resistive load line over a broad range of input currents. Here, in FIG. 1a, the voltage at first base B1 is carried along at a constant interval with the voltage at second base B2. With a declining voltage at second base B2 and at an assumed fixed voltage at first base B1, according to the previous explanation, the amplification increases, which can be compensated by a regulation, effected in FIG. 1a, of first subtransistor Q1 (FIG. 4), therefore a decline in the voltage at first base B1.

The equivalent circuit of the vertically integrated cascode 10 is shown schematically in FIG. 4. This includes two subtransistors Q1 and Q2, whereby in the equivalent circuit the emitter of first transistor Q1 and the collector of second transistor Q2 form a unit. Furthermore, vertically integrated cascode 10 has first base B1, second base B2, collector C, and emitter E.

A vertically integrated cascode 10 is shown schematically in FIG. 5. This has a collector terminal C, a first base terminal B1, and a second base terminal B2, as well as an emitter terminal E. Vertically integrated cascode 10 comprises a collector semiconductor region 1 of a collector C, a first base semiconductor region 2, adjacent to the collector semiconductor region 1, of a first base B1, a second base semiconductor region 4 of a second base B2, an intermediate base semiconductor region 3 adjacent to both the first base semiconductor region 2 and to the second base semiconductor region 4, and an emitter semiconductor region 5, adjacent to the second base semiconductor region 4, of an emitter E. In this case, in the depicted exemplary embodiment, semiconductor regions 1, 3, and 5 are n-doped, whereas semiconductor regions 2 and 4 are p-doped.

The blocking ability of such a vertically integrated cascode 10 is given by the breakdown voltage of base-collector diode 1, 2 of the transistor in the base circuit. Accordingly, in a vertically integrated cascode 10, a collector doping is possible that is higher by a multiple than in a transistor with a comparable blocking ability. In a preferred embodiment of the invention, intermediate base region 3 is not contacted. The potential in uncontacted intermediate base region 3 of vertically integrated cascode 10 depends on the voltage(s) applied at the present contacts and current density.

FIG. 1a shows a configuration of vertically integrated cascode 10 according to the invention. Vertically integrated cascode 10 is thereby configured in such a way that the potential at first base B1 is carried along in the same direction with the potential at second base B2. For this purpose, a network NW of the possibly complex impedances X1 and X2 is provided. A direct current I_{A}, which is impressed by the DC drain CSₙ, flows through impedances X1 and X2. An inductor L, which for high frequencies raises the impedance of the DC drain CSₙ, is connected in series to the DC drain CSₙ. If the impedance of the DC sink CSₙ is sufficiently high, the inductor L can also be omitted.

The operating points for first base B1 and second base B2 are set by the current I_{A} and resistance portions of impedances X1 and X2. Furthermore, the output OUT and a load resistor R_{L} are connected to collector C of cascode 10.

Examples of the network NW are shown in the FIGS. 1b and 1c. These exemplary embodiments show possible networks NW which are especially simple to realize. Alternatively, other networks NW with, for example, active components (diodes, etc.) may also be used.

The exemplary embodiment of FIG. 1b shows the simplest case, in which impedances X1 and X2 are formed by one resistor each R1 and R2. In this case, resistors R1 and R2 represent a substantially frequency-independent voltage divider, which divides the input signal. Another exemplary embodiment for the network NW is shown in FIG. 1c. Here, impedance X1 has an inductor L1 and a resistor R1, which are connected parallel, whereas impedance X2 has a parallel circuit of resistor R2 with a capacitor C2.

Here, inductor L1 with resistor R1 has a high impedance for the appropriate frequency range, whereas capacitor C2 bridges resistor R2 for this frequency range, so that the small signal portions at first base B1 substantially follow the small signal portions at second base B2. If capacitor C2 is designed suitably large, the phase shift between the small signals at first base B1 to the small signals at second base B2 is small.

Naturally, the invention is not limited to the specific circuit example of FIG. 1a. Rather, all electrical couplings, such as current mirror circuits, voltage sources, etc., may be used, which result in the carrying along, in the same direction, of the potential at first base B1 with the potential at second base B2. Preferably, the carrying along is proportional to the second base potential. It is also possible, instead of the vertically integrated cascode 10 of npn transistors Q1, Q2, to use a vertically integrated cascode of suitably complementary pnp transistors.

Another embodiment is shown in FIG. 6. In this case, a current source CSp is provided which is connected to the voltage supply Vcc. This drives a current I_{A} for operating point setting through resistor R2 and through coil L. The current source CSp for the appropriate frequency range thereby has a high impedance, which can be reduced if necessary by the arrangement of resistor R1 and capacitor C1.

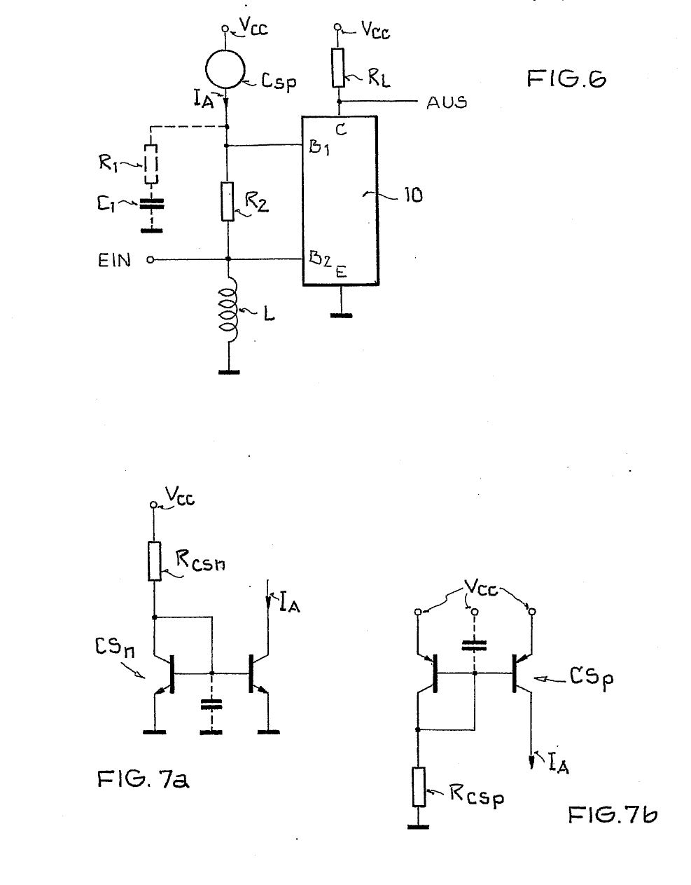

Possible embodiments of the current source CSp or the current drain CSn are the subject of FIGS. 7a and 7b. In the shown cases, the current source CSp and the current drain CSn are realized by a simple current mirror with series-connected resistor R_{CSn} or R_{CSp}. To reduce the effect of the disturbances on the supply voltage Vcc, a capacitor may be connected to the specific base, and which together with the current mirror acts as a low-pass filter.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An amplifier circuit for amplifying an input signal with a vertically integrated cascode comprising:
a collector semiconductor region of a collector;
a first base semiconductor region adjacent to the collector semiconductor region of a first base;
a second base semiconductor region of a second base;
an intermediate base semiconductor region adjacent to both the first base semiconductor region and the second base semiconductor region; and
an emitter semiconductor region, adjacent to the second base semiconductor region of an emitter;
wherein a signal input is connected to the second base, and
wherein the first base is connected via a network to the second base such that a small signal voltage at the first base is coupled to a small signal voltage at the second base and/or a small signal current through the first base to a small signal current through the second base.

2. The amplifier circuit according to claim 1, wherein the first base is connected via the network to the second base such that the small signal voltage at the first base is substantially proportional to the small signal voltage at the second base and/or the small signal current through the first base is substantially proportional to the small signal current through the second base.

3. The amplifier circuit according to claim 1, wherein the network is designed such that the small signal voltage at the first base is substantially in phase to the small signal voltage at the second base and/or the small signal current through the first base is substantially in phase to the small signal current through the second base.

4. The amplifier circuit according to claim 1, wherein the first base is not connected to the collector so that the small signal voltage at the first base and/or the small signal current through the first base are substantially independent of the collector-emitter voltage or the collector current.

5. The amplifier circuit according to claim 1, wherein the network is designed for setting the operating point of the first base and/or the second base.

6. The amplifier circuit according to claim 1, wherein the network has a voltage divider, which is connected to the first base and the second base.

7. The amplifier circuit according to claim 1, wherein the network is designed in such a way that a first base voltage of the first base is fed to a second base voltage of the second base at a substantially constant interval.

8. The amplifier circuit according to claim 1, wherein the first base and the second base are connected to one another via a current mirror.

9. The amplifier circuit according to claim 1, wherein at least one of the base semiconductor regions has a silicon-germanium mixed crystal.

10. The amplifier circuit according to claim 1, wherein the amplifier circuit is a high-frequency circuit for communication technology, mobile radio technology, or automotive technology.

11. A method for amplifying a signal, the method comprising:
providing a cascode circuit;
inputing a signal to an input of the cascode circuit; and
outputting an amplified signal from the cascode circuit,
wherein the cascode circuit comprises:
a collector semiconductor region of a collector;
a first base semiconductor region adjacent to the collector semiconductor region of a first base;
a second base semiconductor region of a second base;
an intermediate base semiconductor region adjacent to both the first base semiconductor region and the second base semiconductor region; and
an emitter semiconductor region, adjacent to the second base semiconductor region of an emitter, the signal input being connected to the second base and the first base is connected via a network to the second base such that a small signal voltage at the first base is coupled to a small signal voltage at the second base and/or a small signal current through the first base to a small signal current through the second base.
